(19) United States
(12) Patent Application Publication
(10) Pub. No.: US 2025/0216690 A1
(43) Pub. Date: Jul. 3, 2025

(54) WAFER PROCESSING APPARATUS AND METHOD OF MANUFACTURING SEMICONDUCTOR DEVICE BY USING THE SAME

(71) Applicant: Samsung Electronics Co., Ltd., Suwon-si (KR)

(72) Inventors: Youngchul KWON, Suwon-si (KR); Namtae HEO, Suwon-si (KR)

(73) Assignee: Samsung Electronics Co., Ltd., Suwon-si (KR)

(21) Appl. No.: 18/788,403

(22) Filed: Jul. 30, 2024

(30) Foreign Application Priority Data
Dec. 27, 2023 (KR) 10-2023-0193175

(51) Int. Cl. G02B 27/09; B23K 26/06; G02B 19/00; H01L 21/268; H01L 21/67

(52) U.S. Cl. CPC G02B 27/0961; B23K 26/0648; G02B 19/0004; G02B 19/0047; G02B 27/0944; H01L 21/67092; H01L 21/268

(57) ABSTRACT

A wafer processing apparatus includes a laser apparatus configured to generate and irradiate a laser beam, a beam shaper configured to shape a waveform of the laser beam, and a beam compressor configured to locally compress the shaped laser beam, wherein the compressed laser beam is input to a wafer.

### CROSS-REFERENCE TO RELATED APPLICATION

This application is based on and claims priority under 35 U.S.C. § 119 to Korean Patent Application No. 10-2023-0193175, filed on Dec. 27, 2023, in the Korean Intellectual Property Office, the disclosure of which is incorporated by reference herein in its entirety.

### BACKGROUND

The inventive concepts relate to a wafer processing apparatus and a method of manufacturing a semiconductor device using the same, and more particularly, to a wafer processing apparatus configured to perform a laser dicing process and a method of manufacturing a semiconductor device by using the wafer processing apparatus.

A laser processing process denotes a process of irradiating a laser beam onto a surface of a processing object to process the physical properties or shape of the surface of the processing object. The laser processing process includes, for example, a patterning process of forming a pattern on a surface of a processing object, a process of deforming the physical properties of the processing object like wafer annealing, a molding process of changing the shape of the processing object through reflow, and a dicing process of dicing the processing object into a plurality of units through reflow.

A wafer dicing process of the related art using a laser beam irradiates a laser beam of a wavelength band having high absorptance onto a processing object to melt the processing object and thus cuts the processing object. In a case which melts and cuts a wafer, a peripheral region as well as a cut region is melted, and due to this, there is a problem where a portion of a semiconductor device formed on the wafer is damaged.

### SUMMARY

The inventive concepts provide a wafer processing apparatus, in which reliability is enhanced and a process speed is enhanced, and a method of manufacturing a semiconductor device by using the wafer processing apparatus.

The object of the inventive concepts is not limited to the aforesaid, but other objects not described herein will be clearly understood by those of ordinary skill in the art from descriptions below.

A wafer processing apparatus according to at least one embodiment includes a laser apparatus configured to generate and irradiate a laser beam, a beam shaper configured to generate a shaped laser beam by shaping a waveform of the laser beam, and a beam compressor configured to locally compress the shaped laser beam, wherein the wafer processing apparatus is configured such that the compressed laser beam is input to a wafer.

A wafer processing apparatus according to at least one embodiment includes a chirped laser beam generator configured to generate and irradiate a laser beam such that wavelength components of the laser beam are time-serially arranged; a beam shaper configured to generate a shaped laser beam by shaping a waveform of the laser beam irradiated by the chirped laser beam generator; and a beam compressor configured to locally compress the shaped laser beam, wherein the wafer processing apparatus is configured such that the compressed laser beam is input to a wafer.

A wafer processing apparatus according to at least one embodiment includes a chirped laser beam generator configured to generate and irradiate a first laser beam such that wavelength components of the first laser beam are time-serially arranged; a beam shaper configured to generate a shaped laser beam by shaping a waveform of the first laser beam to generate a second laser beam; a beam compressor configured to locally compress the second laser beam to generate a third laser beam; and a wafer supporter configured to support a wafer, wherein the wafer processing apparatus is configured such that the third laser beam is input to the wafer.

### BRIEF DESCRIPTION OF THE DRAWINGS

Embodiments will be more clearly understood from the following detailed description taken in conjunction with the accompanying drawings in which:

FIG. 1 is a configuration diagram illustrating a configuration of a wafer processing apparatus according to at least one embodiment;

FIG. 2 is a concept diagram illustrating a chirped laser beam according to at least one embodiment;

FIG. 3 is a diagram illustrating a before-shaping laser beam according to at least one embodiment;

FIG. 4 is a diagram illustrating an after-shaping laser beam according to at least one embodiment;

FIG. 5 is a configuration diagram illustrating a beam shaper according to at least one embodiment;

FIG. 6 is a configuration diagram illustrating a beam shaper according to at least one embodiment;

FIG. 7 is a diagram illustrating a process of compressing a laser beam through diffraction grating, according to at least one embodiment;

FIG. 8 is a configuration diagram illustrating a beam compressor according to at least one embodiment;

FIG. 9 is a diagram illustrating a beam compression apparatus according to at least one embodiment;

FIG. 10 is a configuration diagram illustrating a beam compressor according to at least one embodiment;

FIGS. 11A and 11B are cross-sectional views illustrating a beam compression apparatus according to at least one embodiment;

FIG. 12 is a concept diagram illustrating a laser beam passing through a beam compressor, according to at least one embodiment;

FIG. 13 is a concept diagram illustrating a laser beam input to a wafer, according to at least one embodiment;

FIGS. 14A to 14C are concept diagrams illustrating a laser beam input to a wafer, according to at least one embodiment;

FIG. 15 is a graph showing an effect of a wafer processing apparatus according to at least one embodiment; and

FIG. 16 is a flowchart illustrating a method of manufacturing a semiconductor device, according to at least one embodiment.

### DETAILED DESCRIPTION OF THE EMBODIMENTS

Hereinafter, embodiments will be described in detail with reference to the accompanying drawings. Like reference numerals refer to like elements in the drawings, and their repeated descriptions are omitted. In the drawings, the thickness or size of each layer is exaggerated for convenience of description and clarity, and thus, may slightly differ from a real shape and ratio. Additionally, when the terms “about” or “substantially” are used in this specification in connection with a numerical value and/or geometric terms, it is intended that the associated numerical value includes a manufacturing tolerance (e.g., +10%) around the stated numerical value. Further, regardless of whether numerical values and/or geometric terms are modified as “about” or “substantially,” it will be understood that these values should be construed as including a manufacturing or operational tolerance (e.g., +10%) around the stated numerical values and/or geometry. Additionally, whenever a range of values is enumerated, the range includes all values within the range as if recorded explicitly clearly, and may further include the boundaries of the range. Accordingly, the range of “X” to “Y” includes all values between X and Y, including X and Y.

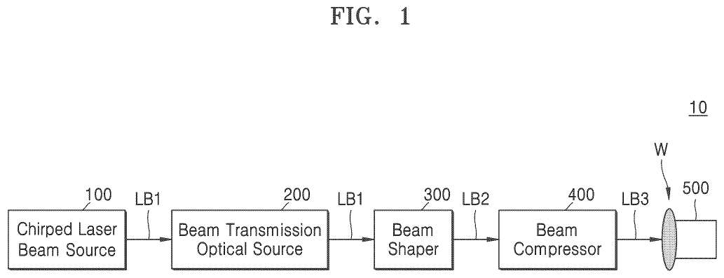

FIG. 1 is a configuration diagram illustrating a configuration of a wafer processing apparatus 10 according to at least one embodiment.

Referring to FIG. 1, the wafer processing apparatus 10 may include a chirped laser beam generator (or source) 100, a beam transmission optical source 200, a beam shaper 300, a beam compressor 400, and a wafer supporter 500.

The wafer processing apparatus 10 may be configured to perform a dicing process. The dicing process may include a process of separating a wafer W, where a semiconductor device is formed, at a high speed with high precision. The dicing process may include a process of irradiating a laser beam LB onto the wafer W to separate the wafer W. That is, the wafer processing apparatus 10 may dice the wafer W by using the laser beam LB. The irradiating a laser beam LB onto the wafer W may also be referred to as inputting the laser beam LB to the wafer W. For example, the laser beam LB may be input to a dice region of the wafer W.

The wafer processing apparatus 10 may dice the wafer W by using a laser beam LB having a nanosecond pulse width and a laser beam LB having an ultrashort pulse width. The laser beam LB having a nanosecond pulse width may include a laser beam LB of a nanosecond scale, and the laser beam LB having an ultrashort pulse width may include a laser beam LB of a femtosecond and/or picosecond scale. For example, the laser beam LB having an ultrashort pulse width may have a pulse width of about 10 picosecond or less. The laser beam LB having a nanosecond pulse width may heat a relatively wide region, and the laser beam LB having an ultrashort pulse width may be relatively precisely irradiated onto the wafer W. The wafer processing apparatus 10 according to at least one embodiment may control an irradiation region of a laser beam LB having the nanosecond pulse width and an irradiation region of a laser beam LB having the ultrashort pulse width to effectively dice the wafer W. Hereinafter, a method of dicing the wafer W by using the laser beam LB having a nanosecond pulse width and the laser beam LB having an ultrashort pulse width is described in detail.

The chirped laser beam generator 100 may generate and irradiate a chirped laser beam LB. The chirped laser beam generator 100 may include a laser source and a laser beam stretcher. The laser source may be configured to generate and irradiate a laser beam LB of a nanosecond scale. For example, the laser source may include an Nd:YAG laser and/or an excimer laser.

The laser beam stretcher may be configured to move various wavelength components of a pulse of the laser beam LB at various speeds. The laser beam stretcher may be configured to extend the pulse of the laser beam LB based on time. For example, the laser beam stretcher may increase the duration of the pulse by using a dispersion characteristic of light. Here, the dispersion characteristic of light may denote that the speed at which a material moves is changed based on the wavelength of light. That is, in a case where the laser beams LB pass through a medium, the laser beams LB may be time-serially arranged based on the wavelength of each of the laser beams LB. For example, the laser beam stretcher may include an optical fiber or a diffraction grating.

The laser beam LB generated by the chirped laser beam generator 100 may have a pulse width of a nanosecond scale. For example, the laser beam LB may have a pulse width of about 1 nanosecond to about 1,000 nanoseconds. Also, the laser beam LB may have a wavelength of about 600 nanosecond or less.

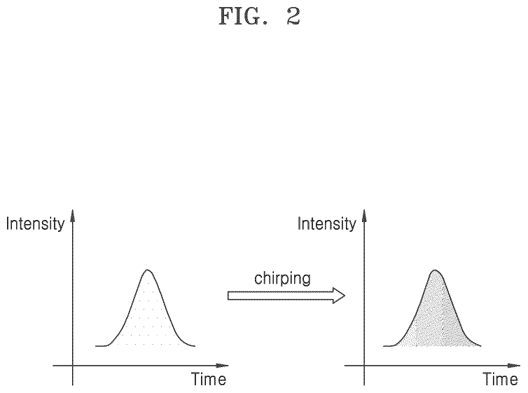

In the laser beams LB generated by the chirped laser beam generator 100, wavelength components of the laser beams LB may be time-serially arranged. Hereinafter, for convenience of description, the laser beam LB generated by the chirped laser beam generator 100 may be referred to as a chirped laser beam. The chirped laser beam is described below with reference to FIG. 2.

FIG. 2 is a concept diagram illustrating a chirped laser beam according to at least one embodiment. For convenience of description, a case where a laser beam has a pulse type is illustrated for example. FIG. 2 illustrates the intensity of a laser beam LB with respect to time. In FIG. 2, the abscissa axis represents time, and the ordinate axis represents intensity. FIG. 2 may be described in conjunction with FIG. 1.

Referring to FIG. 2, the laser source may generate and irradiate a laser beam LB. The laser beam LB generated by the laser source may be referred to as a normal laser beam. Also, a laser beam passing through the laser beam stretcher may be referred to as a chirped laser beam.

The frequency or wavelength of the normal laser beam may be maintained to be constant. On the other hand, the frequency or wavelength of the chirped laser beam may linearly and/or non-linearly increase and/or decrease. For example, light having a long wavelength of the chirped laser beam may be arranged prior to light having a short wavelength. In other embodiments, light having a short wavelength of the chirped laser beam may be arranged prior to light having a long wavelength.

Referring again to FIG. 1, the laser beam LB generated by the chirped laser beam generator 100 may be input to the beam transmission optical source 200. The beam transmission optical source 200 may transfer the laser beam LB, generated by the chirped laser beam generator 100, to the beam shaper 300. The beam transmission optical source 200 may be or include, for example, free space optics, but is not limited thereto. The beam transmission optical source 200 may include various optical elements such as a polarizer, a lens, a reflector, a prism, and a splitter.

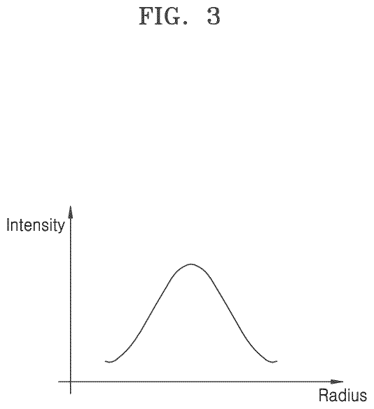

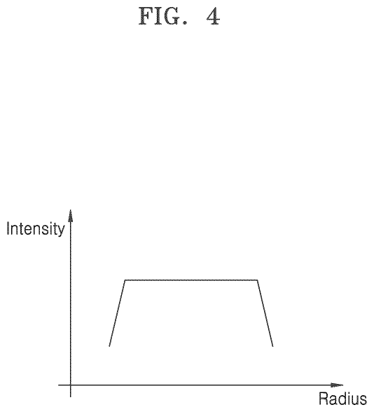

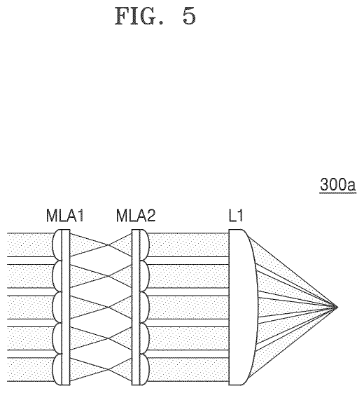

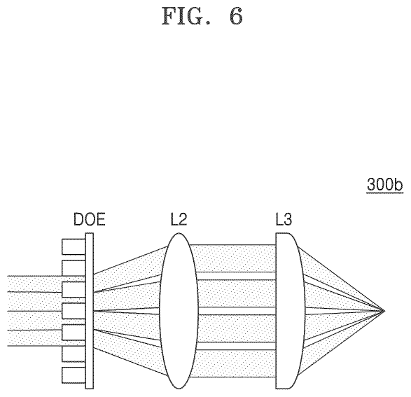

The beam shaper 300 may receive a laser beam LB from the beam transmission optical source 200. The beam shaper 300 may shape a waveform of the laser beam LB. An operation of shaping a waveform of the laser beam LB by using the beam shaper 300 is described below with reference to FIGS. 3 and 4. Also, a configuration of the beam shaper 300 is described below with reference to FIGS. 5 and 6.

FIGS. 3 and 4 are diagrams illustrating a beam shaper 300 according to at least one embodiment. In detail, FIG. 3 is a diagram illustrating a before-shaping laser beam according to at least one embodiment, and FIG. 4 is a diagram illustrating an after-shaping laser beam according to at least one embodiment. For convenience of description, a case where a laser beam LB has a pulse type is illustrated for example. A before-shaping laser beam LB may be referred to as a first laser beam LB1, and an after-shaping laser beam LB may be referred to as a second laser beam LB2. Each of FIGS. 3 and 4 illustrates the intensity of a laser beam LB with respect to a radius. In FIGS. 3 and 4, the abscissa axis represents a radius and the ordinate axis represents intensity. In FIGS. 3 and 4, the same positions are aligned with each other to represent the same positions in the abscissa axis.

Referring to FIGS. 3 and 4, a waveform of the first laser beam LB1 may differ from that of the second laser beam LB2. The peak region of the first laser beam LB1 may be a region adjacent to the center region of a laser beam LB of a wafer W. The peak region of a waveform of the second laser beam LB2 may be wider than the peak region of a waveform of the first laser beam LB1. The first laser beam LB1 may have a waveform which has a relatively steep slope near the center region of the laser beam LB, and the second laser beam LB2 may have a waveform which has a relatively gentle slope near the center region of the laser beam LB. That is, the first laser beam LB1 may have a waveform which has a relatively steep slope in the outer region of the laser beam LB, and the second laser beam LB2 may have a waveform which has a relatively gentle slope in the outer region of the laser beam LB. Also, the second laser beam LB2 may decrease in intensity of the laser beam LB at the peak, compared to the first laser beam LB1. That is, the beam shaper 300 may adjust a ratio of the peak of the laser beam LB in each of the center region and the outer region of the laser beam LB.

The second laser beam LB2 may have a waveform having a relatively gentle slope in the outer region, and thus, the intensity of the outer region of the laser beam LB may increase compared to the intensity of the center region of the laser beam LB. Although described below, a laser beam LB having a pulse width of a nanosecond scale may be irradiated onto the center region of the laser beam LB, and a laser beam LB having an ultrashort pulse width may be irradiated onto the outer region of the laser beam LB. That is, because the laser beam LB is shaped, a ratio of intensity of a laser beam LB having an ultrashort pulse width may increase compared to a laser beam LB having a pulse width of a nanosecond scale.

FIGS. 5 and 6 are configuration diagrams illustrating a beam shaper according to at least one embodiment. In detail, FIG. 5 illustrates a case where a beam shaper 300a includes a plurality of micro lens arrays MLA, and FIG. 6 illustrates a case where a beam shaper 300b includes a diffraction optical element DOE and a micro lens array.

Referring to FIG. 5, the beam shaper 300a may include a plurality of micro lens arrays (for example, first and second micro lens arrays) MLA1 and MLA2 and a first lens L1. A micro lens array may include a plurality of lenses which are arranged in a grating shape. For example, the first micro lens array MLA1 and the second micro lens array MLA2 may split a laser beam LB incident thereon into a plurality of reduced laser beams LB. A laser beam LB passing through the first micro lens array MLA1 and the second micro lens array MLA2 may be collected by the first lens L1. The waveform of the laser beam LB may be shaped by using the first micro lens array MLA1 and the second micro lens array MLA2.

Referring to FIG. 6, the beam shaper 300b may include a diffraction optical element DOE and a plurality of lenses L2 and L3. The diffraction optical element DOE may adjust a laser beam LB based on the diffraction principle. The diffraction optical element DOE may adjust the waveform of the laser beam LB. The laser beam LB passing through the diffraction optical element DOE may pass through the second lens L2 and the third lens L3 and converge. The diffraction optical element DOE may shape the waveform of the laser beam LB.

Hereinabove, a case in which the laser beam LB is shaped by using the micro lens array MLA and the diffraction optical element DOE has been described above. However, the inventive concepts are not limited thereto, and another method of shaping the laser beam LB may be used.

For example, the micro lens array MLA and the diffraction optical element DOE may be variously arranged, and thus, the waveform of the laser beam LB may have a shape having arbitrary flatness.

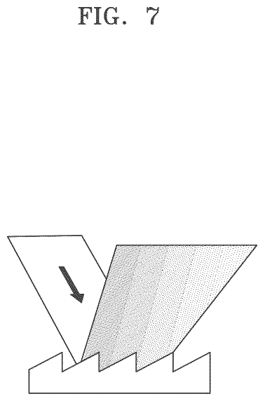

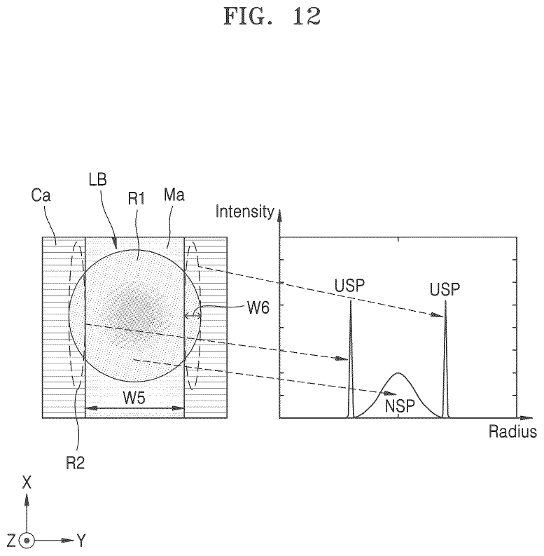

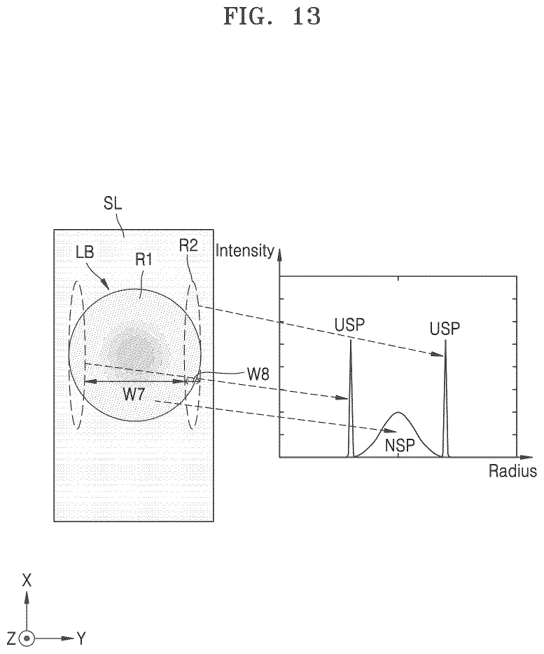

Referring again to FIG. 1, a waveform-shaped laser beam LB2 passing through the beam shaper 300 may be input to the beam compressor 400. The beam compressor 400 may compress at least a portion of the laser beam LB. For example, the beam compressor 400 may compress a portion of the laser beam LB and may not compress the other portion of the laser beam LB. A configuration of the beam compressor 400 is described below with reference to FIGS. 7 to 11B. Also, a laser beam LB compressed by the beam compressor 400 is described below with reference to FIGS. 12 and 13.

FIG. 7 is a diagram illustrating a process of compressing a laser beam through diffraction grating, according to at least one embodiment. In FIG. 7, the arrow represents a traveling direction of a laser beam incident on the diffraction grating.

Referring to FIG. 7, the diffraction grating may include a sawtooth pattern. The diffraction grating may include a sawtooth pattern which is periodically patterned. In a beam incident on the diffraction grating, a light path may be differently assigned based on an incident order of beams. For example, according to the diffraction grating of FIG. 7, a light path of a succeeding beam in one pattern may be shorter than a light path of a preceding beam. That is, the diffraction grating may control a phase relationship of a diffracted beam to compress a laser beam LB. That is, the laser beam LB passing through the diffraction grating may be compressed.

Also, the degree of compression of the laser beam LB may be adjusted based on the spacing, slope, and/or direction of a pattern of the diffraction grating. For example, when the slope of the sawtooth pattern of the diffraction pattern increases, the degree of compression of the laser beam LB may be changed. For example, when the slope of the sawtooth pattern of the diffraction pattern increases, the degree of compression of the laser beam LB may increase. Also, when the direction of the sawtooth pattern of the diffraction pattern rotates, the degree of compression of the laser beam LB may be changed.

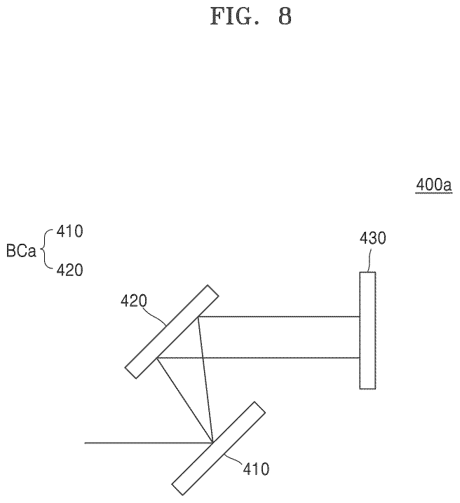

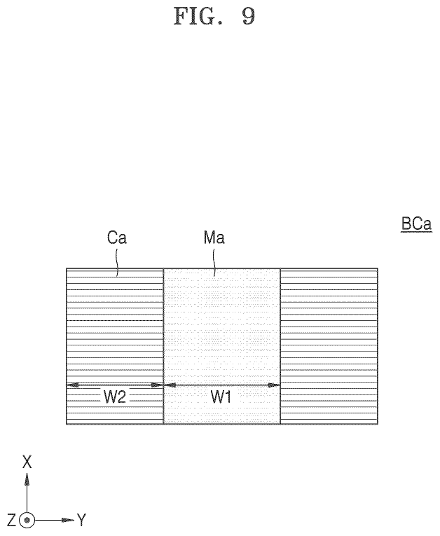

FIG. 8 is a configuration diagram illustrating a beam compressor 400a according to at least one embodiment. FIG. 9 is a diagram illustrating a beam compression apparatus BCa according to at least one embodiment.

Referring to FIGS. 8 and 9, the beam compressor 400a may include a first beam compression apparatus 410, a second beam compression apparatus 420, and a mirror 430. In FIG. 8, the beam compressor 400a is illustrated as including two beam compression apparatuses BCa, but is not limited thereto and may include one or more beam compression apparatuses BCa. A laser beam irradiated onto the beam compressor 400a may pass through the first beam compression apparatus 410 and the second beam compression apparatus 420, and at least a portion thereof may be compressed. The beam compressor 400a may decrease the pulse width of a laser beam LB.

The beam compression apparatus BCa may include a mirror region Ma and a compression region Ca. The mirror region Ma may be a region where a mirror is disposed, and the laser beam LB incident on the mirror region Ma may not be compressed and may be reflected. That is, the beam compression apparatus BCa may locally compress the laser beam LB. The compression region Ca may be configured to compress the laser beam LB. For example, the compression region Ca may include the diffraction grating pattern described above with reference to FIG. 7. In other embodiments, the compression region Ca may include a spatial light modulator including the diffraction grating pattern.

The beam compression apparatus BCa may include a plurality of mirror regions Ma. The compression region Ca may be disposed between the plurality of mirror regions Ma. The mirror region Ma may be disposed in the center region of the beam compression apparatus BCa, and the compression region Ca may be disposed in the outer region of the beam compression apparatus BCa. That is, the center region of the laser beam LB may not be compressed, and the outer region of the laser beam LB may be compressed. In some embodiments, the compression region Ca may be provided in a plurality of compression regions Ca, and the mirror region Ma (e.g., one mirror region Ma) may be provided between the plurality of compression regions Ca (e.g., two of the plurality of compression regions Ca).

As described above, the laser beam LB may have a pulse width of a nanosecond scale based on the chirped laser beam generator 100. For example, the laser beam LB may have a pulse width of about 1 ns (nanosecond) to about 1,000 ns. The beam compression apparatus BCa may compress the pulse width of at least a portion of the laser beam LB. For example, the beam compression apparatus BCa may perform compression so that at least a portion of the laser beam LB has a pulse width of about 1 femtosecond to about 1 nanosecond. That is, the beam compression apparatus BCa may perform compression so that at least a portion of the laser beam LB has a femtosecond and/or picosecond scale. Also, the wavelength of a before-compression laser beam LB may be substantially the same as that of an after-compression laser beam LB.

The mirror region Ma may have a first width W1 in a horizontal direction (an X direction and/or a Y direction), and the compression region Ca may have a second width W2 in the horizontal direction (the X direction and/or the Y direction). The first width W1 may be greater than the second width W2. For example, a range of the first width W1 may be about 1 mm (millimeter) to about 10 mm, and a range of the second width W2 may be about 0.5 mm to about 5 mm. A ratio of the second width W2 to the first width W1 may be variously changed depending on the case. In other embodiments, the first width W1 may be less than the second width W2. Although described below, when the second width W2 is about 0.5 mm or more, the laser beam LB having an ultrashort pulse width may have high reliability without being dispersed.

In FIGS. 8 and 9, the horizontal direction (the X direction and/or the Y direction) may be defined as a direction parallel to a main surface of the beam compression apparatus BCa, and the vertical direction (a Z direction) may be defined as a direction perpendicular to the horizontal direction (the X direction and/or the Y direction).

As described below, a compressed laser beam LB may be decreased more, in duration of a pulse, than a before-compression laser beam LB, and thus, the intensity of a peak of a pulse may increase.

In FIG. 9, it is illustrated that regions have the same degree of compression in the compression region Ca, but the inventive concepts are not limited thereto. For example, a plurality of regions which differ in degree of compression may be disposed in the compression region Ca.

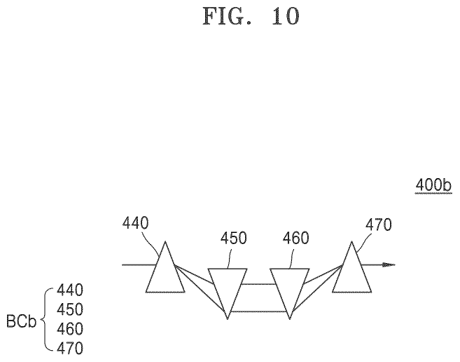

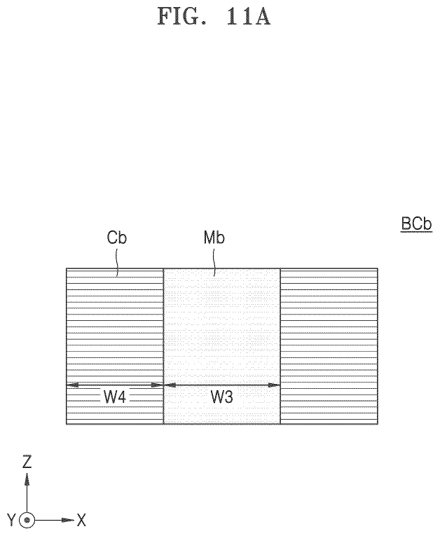

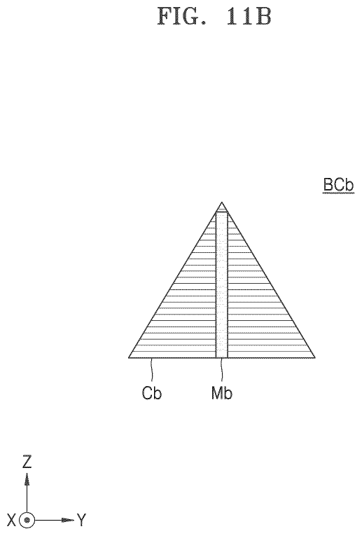

FIG. 10 is a configuration diagram illustrating a beam compressor 400b according to at least one embodiment. FIGS. 11A and 11B are cross-sectional views illustrating a beam compression apparatus BCb according to at least one embodiment. FIGS. 11A and 11B illustrate cross-sectional views of a beam compression apparatus of FIG. 10. FIG. 11A illustrates a cross-sectional view of the beam compression apparatus of FIG. 10 from the front, and FIG. 11B illustrates a cross-sectional views of the beam compression apparatus of FIG. 10 from the side.

Referring to FIGS. 10 to 11B, the beam compressor 400b may include third to sixth beam compression apparatuses 440 to 470. In FIG. 10, the beam compressor 400b is illustrated as including four beam compression apparatuses BCb, but is not limited thereto and may include one or more beam compression apparatuses BCb. A laser beam LB incident on the beam compressor 400b may pass through the third to sixth beam compression apparatuses 440 to 470, and at least a portion of the laser beam LB may be compressed. The beam compressor 400b may decrease the pulse width of the laser beam LB. For example, the beam compression apparatus BCb may perform compression so that at least a portion of the laser beam LB has a pulse width of about 1 femtosecond to about 1 nanosecond. Also, the wavelength of a before-compression laser beam LB may be substantially the same as that of an after-compression laser beam LB.

The beam compression apparatus BCb may include a mirror region Mb and a compression region Cb. The beam compression apparatus BCb may have a tetragonal shape when seen in a direction (e.g., from the front) parallel to a direction in which the laser beam LB travels and may have a triangular shape when seen in a direction (e.g., from the side) perpendicular to the direction in which the laser beam LB travels. As illustrated in FIG. 11A, in the front view, the mirror region Mb and the compression region Cb may have a tetragonal shape. Also, as illustrated in FIG. 11B, in the side view, the mirror region Mb may have a tetragonal shape and the compression region Cb may have a triangular shape.

The mirror region Mb may be a region where a mirror is disposed, and the laser beam LB incident on the mirror region Mb may not be compressed and may be reflected. That is, the beam compression apparatus BCb may locally compress the laser beam LB. The compression region Cb may be configured to compress the laser beam LB. For example, the compression region Cb may include a prism. In other embodiments, the compression region Cb may include a transmissive diffraction grating element. For example, the compression region Cb may include a spatial light modulator including the diffraction grating pattern.

The beam compression apparatus BCb may include a plurality of mirror regions Mb. The compression region Cb may be disposed between the plurality of mirror regions Mb. The mirror region Mb may be disposed in the center region of the beam compression apparatus BCb, and the compression region Cb may be disposed in the outer region of the beam compression apparatus BCb. That is, the center region of the laser beam LB may not be compressed, and the outer region of the laser beam LB may be compressed. In some embodiments, the compression region Cb may be provided in a plurality of compression regions Cb, and the mirror region Mb (e.g., one mirror region Mb) may be provided between the plurality of compression regions Cb (e.g., two of the plurality of compression regions Cb).

As described above, the laser beam LB may have a pulse width of a nanosecond scale based on the chirped laser beam generator 100. For example, the laser beam LB may have a pulse width of about 1 ns (nanosecond) to about 1,000 ns. The beam compression apparatus BCb may compress the pulse width of at least a portion of the laser beam LB. For example, the beam compression apparatus BCb may perform compression so that at least a portion of the laser beam LB has a pulse width of about 1 fs (femtosecond) to about 1 ns. That is, the beam compression apparatus BCb may perform compression so that at least a portion of the laser beam LB has a femtosecond and/or picosecond scale. Also, the wavelength of a before-compression laser beam LB may be substantially the same as that of an after-compression laser beam LB.

The mirror region Mb may have a third width W3 in a first horizontal direction (an X direction), and the compression region Cb may have a fourth width W4 in the first horizontal direction (the X direction). The third width W3 may be greater than the fourth width W4. For example, a range of the third width W3 may be about 1 mm to about 10 mm and a range of the fourth width W4 may be about 0.5 mm to about 5 mm. A ratio of the fourth width W4 to the third width W3 may be variously changed depending on the case. In other embodiments, the third width W3 may be less than the fourth width W4. Although described below, when the fourth width W4 is about 0.5 mm or more, the laser beam LB having an ultrashort pulse width may have high reliability without being dispersed.

In FIGS. 10 to 11B, the horizontal direction (the X direction and/or the Y direction) may be defined as a direction parallel to the lower surface of the beam compression apparatus BCb, and the vertical direction (a Z direction) may be defined as a direction perpendicular to the horizontal direction (the X direction and/or the Y direction).

In FIGS. 10 to 11B, a case where the beam compression apparatus BCb includes a prism and a mirror is illustrated. However, at least one embodiment is not limited thereto, and for example, the beam compression apparatus BCb may include a graded index prism where a refractive index is changed based on a position and/or a graded thickness prism where a thickness is changed based on a position. The beam compression apparatus BCb may also differ in degree of compression based on an incident position.

Hereinabove, a configuration where the laser beam LB is locally compressed by using a diffraction grating and a prism has been described with reference to FIGS. 7 to 11B. However, the inventive concepts are not limited thereto. For example, a configuration of compressing the laser beam LB by using an optical fiber may be possible.

In FIGS. 11A and 11B, it is illustrated that regions have the same degree of compression in the compression region Cb, but the inventive concepts are not limited thereto. For example, a plurality of regions which differ in degree of compression may be disposed in the compression region Cb.

FIG. 12 is a concept diagram illustrating a laser beam passing through a beam compressor, according to at least one embodiment. In FIG. 12, for example, a case where the beam compressor 400 includes the beam compression apparatus BCa of FIG. 8 (e.g., the diffraction grating pattern) is illustrated. In FIG. 12, the schematic shape of a laser beam LB incident on the beam compressor 400 is illustrated on the left side, and the intensity of the laser beam LB is illustrated in the right graph. The right graph illustrates the intensity of the laser beam LB with respect to a radius. The abscissa axis of the right graph represents a radius, and the ordinate axis represents the intensity of the laser beam LB. In the graph, NSP may denote a laser beam LB having a nanosecond pulse width and USP may denote a laser beam LB having an ultrashort pulse width.

Referring to FIG. 12, at least a portion of a laser beam LB incident on the beam compression apparatus BCa may be incident on a mirror region Ma of the beam compression apparatus BCa, and the other portion of the laser beam LB may be incident on a compression region Ca of the beam compression apparatus BCa. As described above, the laser beam LB incident on the mirror region Ma may not be compressed, and the laser beam LB incident on the compression region Ca may be compressed. A region of the laser beam LB incident on the mirror region Ma may be referred to as a first region R1, and a region of the laser beam LB incident on the compression region Ca may be referred to as a second region R2. A laser beam LB of the first region R1 may not be compressed and may maintain a pulse width of a nanosecond scale, and a laser beam LB of the second region R2 may be compressed and may have an ultrashort pulse width.

In the right graph, the laser beam LB corresponding to the first region R1 may have a pulse width of a nanosecond scale, and thus, may be relatively small in intensity of a peak. On the other hand, the laser beam LB corresponding to the second region R2 may have an ultrashort pulse width, and thus, may be relatively large in intensity of a peak. The laser beam LB having a pulse width of a nanosecond scale may affect a relatively wide region, but the intensity thereof may be relatively low. On the other hand, the laser beam LB having an ultrashort pulse width may affect a relatively narrow region, but the intensity thereof may be relatively large.

Pulse widths of laser beams LB irradiated onto the first region R1 and the second region R2 may differ. That is, the pulse width of the laser beam LB irradiated onto the first region R1 may be greater than that of the laser beam LB irradiated onto the second region R2. The first region R1 (e.g., a region near the center region of the laser beam LB) may have a pulse width of a nanosecond scale, and the second region R2 (e.g., the outer region of the laser beam LB) may have an ultrashort pulse width. In other embodiments, the first region R1 (e.g., the region near the center region of the laser beam LB) may have a pulse width of about 10 ps (picosecond) to about 300 femtoseconds (e.g., about 20 picosecond to about 300 femtoseconds), and the second region R2 (e.g., the outer region of the laser beam LB) may have a pulse width of about 1 femtosecond to about 200 femtoseconds. In this case, the chirped laser beam generator 100 may generate and irradiate a laser beam LB having an ultrashort pulse width, and/or all of the laser beams LB of the center region and the outer region may be compressed.

The first region R1 may have a fifth width W5 in a horizontal direction (an X direction and/or a Y direction), and the second region R2 may have a sixth width W6 in the horizontal direction (the X direction and/or the Y direction). The fifth width W5 may be greater than the sixth width W6. For example, a range of the fifth width W5 may be about 1 mm to about 10 mm, and a range of the sixth width W6 may be about 0.5 mm to about 5 mm. A ratio of the sixth width W6 to the fifth width W5 may be variously changed depending on the case. Also, the fifth width W5 may be substantially the same as the first width W1 of FIGS. 8 and 9, and the sixth width W6 may be less than or equal to the second width W2 of FIGS. 8 and 9. When the sixth width W6 is less than or equal to a certain numerical value, the dispersion of the laser beam LB may occur. Accordingly, the sixth width W6 may be about 0.5 mm or more.

In FIG. 12, the horizontal direction (the X direction and/or the Y direction) may be defined as a direction parallel to a main surface of the beam compression apparatus BCa, and the vertical direction (a Z direction) may be defined as a direction perpendicular to the horizontal direction (the X direction and/or the Y direction).

The beam compressor 400 may locally compress the laser beam LB, and particularly, may locally compress the outer region of the laser beam LB. Accordingly, the beam compressor 400 may control the laser beam LB so that the center region of the laser beam LB has a pulse width of a nanosecond scale, and the outer region of the laser beam LB has an ultrashort pulse width.

As described above, the laser beam LB of the second region R2 may be formed by compressing the laser beam LB of the first region R1, and thus, a pulse width may be relatively short and the intensity of a peak may be relatively large.

FIG. 13 is a concept diagram illustrating a laser beam input to a wafer, according to at least one embodiment. In FIG. 13, the schematic shape of a laser beam LB incident on a scribe lane region SL of a wafer W is illustrated on the left side, and the intensity of the laser beam LB is illustrated in the right graph. The right graph illustrates the intensity of the laser beam LB with respect to a radius. The abscissa axis of the right graph represents a radius, and the ordinate axis represents the intensity of the laser beam LB. In the graph, NSP may denote a laser beam LB having a nanosecond pulse width and USP may denote a laser beam LB having an ultrashort pulse width.

The scribe lane region SL may denote a region which defines a device formation region, where a semiconductor device is disposed, of the wafer W. A wafer processing apparatus 10 may irradiate a laser beam LB onto the wafer W along the scribe lane region SL to dice the wafer W.

Also, a direction in which a laser beam LB having an ultrashort pulse width is apart from the center region of the laser beam LB may be perpendicular to an extension direction of the scribe lane region SL of the wafer W. That is, a direction in which a second region R2 is apart from the center region of the laser beam LB may be perpendicular to the extension direction of the scribe lane region SL of the wafer W. The laser beam LB may move in the extension direction of the scribe lane region SL of the wafer W. A moving direction of the laser beam LB may be perpendicular to a direction in which the second region R2 is apart from the center region of the laser beam LB.

For example, the extension direction of the scribe lane region SL may be parallel to a first horizontal direction (an X direction). Also, the direction in which the second region R2 is apart from the center region of the laser beam LB may be parallel to a second horizontal direction (a Y direction).

A first region R1 may have a seventh width W7 in a horizontal direction (the X direction and/or the Y direction), and the second region R2 may have an eighth width W8 in the horizontal direction (the X direction and/or the Y direction). The seventh width W7 may be greater than the eighth width W8. For example, a range of the seventh width W7 may be about 1 mm to about 10 mm and a range of the eighth width W8 may be about 0.5 mm to about 5 mm. A ratio of the eighth width W8 to the seventh width W7 may be variously changed depending on the case. When the eighth width W8 is less than or equal to a certain numerical value, the dispersion of the laser beam LB may occur. Accordingly, the eighth width W8 may be about 0.5 mm or more.

In FIG. 13, the horizontal direction (the X direction and/or the Y direction) may be defined as a direction parallel to a main surface of the wafer W, and the vertical direction (a Z direction) may be defined as a direction perpendicular to the horizontal direction (the X direction and/or the Y direction).

Referring again to FIG. 1, the laser beam LB passing through the beam compressor 400 may be input to the wafer W. The wafer W may be and/or include a semiconductor, for example, a semiconductor elements such as silicon (Si), germanium (Ge), etc., and/or a compound semiconductor such as silicon carbide (SiC), gallium arsenide (GaAs), indium arsenide (InAs), indium phosphide (InP), etc.

In some embodiments, the wafer W may have a silicon on insulator (SOI) structure. The wafer W may include a buried oxide layer formed on a front-side surface of the wafer W. In some embodiments, the wafer W may include a conductive region (for example, an impurity-doped well) formed on the front-side surface of the wafer W. In some embodiments, the wafer W may have various device isolation structures such as a shallow trench isolation (STI) which isolates the impurity-doped well. Although not shown, a plurality of material layers may be formed on the front-side surface of the wafer W. At least one material layer may be formed on a backside surface of the wafer W.

The wafer W may include a semiconductor device formed on the wafer W. The wafer W may include a plurality of device formation regions (where the semiconductor device is formed) and a scribe lane region (which defines the plurality of device formation regions).

A semiconductor device SD formed in the wafer W may be at least one of a memory device and/or a non-memory device. In some embodiments, the memory device may be a non-volatile memory semiconductor device such as flash memory, phase-change random access memory (PRAM), magnetoresistive random access memory (MRAM), ferroelectric random access memory (FeRAM), resistive random access memory (RRAM), and/or the like. The flash memory may be, for example, V-NAND flash memory. In some other embodiments, the memory device may be a volatile memory semiconductor device such as dynamic random access memory (DRAM), static random access memory (SRAM), and/or the like. For example, the memory device may be a volatile memory device where data is lost when power thereto is cut off. In some embodiments, the non-memory device may be a logic chip such as a central processing unit (CPU), a graphics processing unit (GPU), or an application processor (AP). In some embodiments, the non-memory device may be a measurement device, a communication device, a digital signal processor (DSP), or a system on chip (SoC).

The wafer W may be disposed on a wafer supporter 500. The wafer supporter 500 may support the wafer W, which is processed by using a laser. In embodiments, the wafer supporter 500 may be a vacuum chuck configured to support the wafer W by using vacuum pressure. Alternatively, the wafer supporter 500 may be an electrostatic chuck, a chuck including a clamp means which physically supports the wafer supporter 500, etc.

Hereinabove, a process of processing (for example, dicing) the wafer W by using the wafer processing apparatus 10 has been described. First, a first laser beam LB1 generated by the chirped laser beam generator 100 may be input to the beam shaper 300 via the beam transmission optical source 200. The waveform of the first laser beam LB1 input to the beam shaper 300 may be changed, and thus, a second laser beam LB2 may be generated. The second laser beam LB2 may have a gentle peak compared to the first laser beam LB1 and may decrease in peak intensity. A waveform-changed second laser beam LB2 may be input to the beam compressor 400. The beam compressor 400 may locally compress the second laser beam LB2. In more detail, the beam compressor 400 may not compress the center region of the second laser beam LB2 and may compress the outer region of the second laser beam LB2. For example, the beam compressor 400 may perform control so that the center region of the second laser beam LB2 has a pulse width of a nanosecond scale and may perform control so that the outer region of the second laser beam LB2 has an ultrashort pulse width, thereby generating a third laser beam LB3. The third laser beam LB3 generated by the beam compressor 400 may be input to the wafer W. The third laser beam LB3 input to the wafer W may heat the wafer W, and thus, a heated wafer W may be diced. In at least one embodiment, the process may be controlled (and/or enabled by) processing circuitry, such as hardware, software, or a combination thereof configured to perform a specific function. For example, the wafer processing apparatus 10 may include and/or be controlled by processing circuitry configured to control the operations (e.g., timing, intensity, loading, etc.) of the wafer processing apparatus 10. The processing circuitry, more specifically, may include (and/or be included in), but is not limited to, a central processing unit (CPU), a neural processing unit (NPU), deep learning processor (DLP), an arithmetic logic unit (ALU), a digital signal processor, a microcomputer, a field programmable gate array (FPGA), and programmable logic unit, a microprocessor, application-specific integrated circuit (ASIC), etc.

A general wafer processing apparatus processes a wafer by using a laser beam having a pulse width of a nanosecond scale, or processes a wafer by using a laser beam having an ultrashort pulse width. The laser beam having a pulse width of a nanosecond scale may process a relatively wide region, but a heat affected zone (HAZ) may be generated and damage a wafer. In more detail, the laser beam having a pulse width of a nanosecond scale may heat a wafer to dice the wafer, and thus, a wide HAZ may be generated. On the other hand, a laser beam having an ultrashort pulse width may have high reliability and may precisely process a wafer but may process a relatively narrow region, whereby there may be a probability that productivity is low.

On the other hand, the wafer processing apparatus 10 according to at least one embodiment may process the wafer W by using a laser beam LB including a region having a pulse width of a nanosecond scale and a region having an ultrashort pulse width. Accordingly, as a laser beam having a pulse width of a nanosecond scale is disposed in the center region of the laser beam LB, a relatively wide region may be processed, and moreover, as a laser beam LB having an ultrashort pulse width is disposed in the outer region of the laser beam LB, damage to wafer W may be prevented. As a result, the wafer processing apparatus 10 according to at least one embodiment may have high reliability and a high process speed and may process the wafer W.

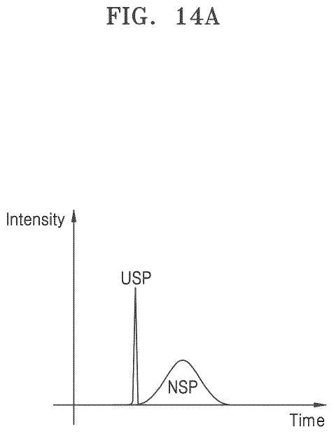

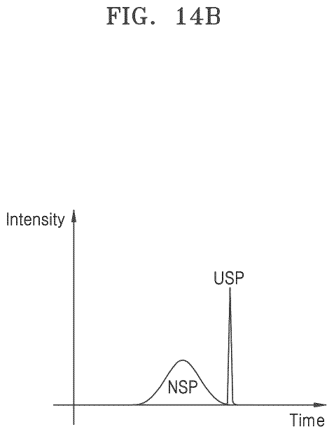

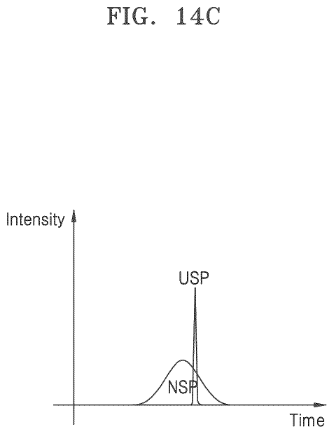

FIGS. 14A to 14C are concept diagrams illustrating a laser beam LB input to a wafer, according to at least one embodiment. In FIGS. 14A to 14C, the intensity of a laser beam LB is shown with respect to time at an arbitrary position of a wafer W. In FIGS. 14A to 14C, the abscissa axis represents time and the ordinate axis represents the intensity of the laser beam LB. In the graph, NSP may denote a laser beam LB having a nanosecond pulse width and USP may denote a laser beam LB having an ultrashort pulse width. FIGS. 14A to 14C may be described in conjunction with FIGS. 1 to 13.

Referring to FIGS. 14A to 14C, a laser beam LB may include a laser beam LB having a nanosecond pulse width and a laser beam LB having an ultrashort pulse width. The laser beam LB having a nanosecond pulse width and the laser beam LB having an ultrashort pulse width may be variously combined and irradiated onto an arbitrary region of a wafer W. For example, FIG. 14A illustrates a case where the laser beam LB having an ultrashort pulse width is irradiated onto the wafer W, and then, the laser beam LB having a nanosecond pulse width is irradiated onto the wafer W. FIG. 14B illustrates a case where the laser beam LB having a nanosecond pulse width is irradiated onto the wafer W, and then, the laser beam LB having an ultrashort pulse width is irradiated onto the wafer W. FIG. 14C illustrates a case where the laser beam LB having an ultrashort pulse width is irradiated onto the wafer W while the laser beam LB having a nanosecond pulse width is being irradiated onto the wafer W. That is, the laser beam LB having a nanosecond pulse width and the laser beam LB having an ultrashort pulse width may be combined in sequence and irradiated onto the wafer W, depending on the case.

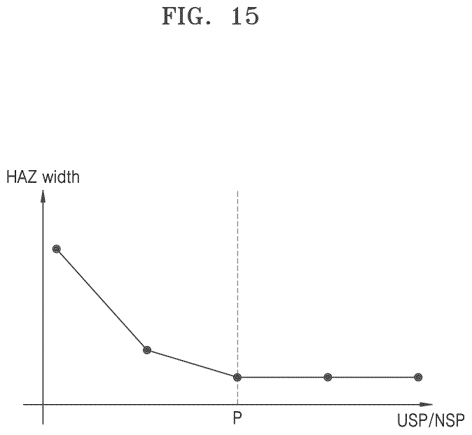

FIG. 15 is a graph showing an effect of a wafer processing apparatus 10 according to at least one embodiment. FIG. 15 shows the width of an HAZ with respect to a ratio of intensity of a laser beam LB having an ultrashort pulse width to intensity of a laser beam LB having a nanosecond pulse width. The abscissa axis of the graph of FIG. 15 represents a ratio (USP/NSP) of the intensity of the laser beam LB having an ultrashort pulse width to the intensity of the laser beam LB having a nanosecond pulse width, and the ordinate axis represents the width of the HAZ. FIG. 15 may be described in conjunction with FIGS. 1 to 14C.

Referring to FIG. 15, it may be seen that, as the ratio (USP/NSP) of the intensity of the laser beam LB having an ultrashort pulse width to the intensity of the laser beam LB having a nanosecond pulse width increases, the width of the heat affected zone (HAZ) is reduced and is then maintained at a certain level. Therefore, when the ratio (USP/NSP) of the intensity of the laser beam LB having an ultrashort pulse width to the intensity of the laser beam LB having a nanosecond pulse width increases before a certain point (for example, a P point), the width of the HAZ may be reduced.

In a case where the laser beam LB heats a wafer W, a peripheral region of an irradiation region of the laser beam LB may be heated and melted by the laser beam LB. Accordingly, the HAZ may decrease the reliability of the wafer W. The HAZ may be generated based on the laser beam LB having an ultrashort pulse width and the laser beam LB having a nanosecond pulse width.

However, when the laser beam LB having an ultrashort pulse width and the laser beam LB having a nanosecond pulse width have the same intensity, the width of an HAZ generated by the laser beam LB having a nanosecond pulse width may be greater than that of an HAZ generated by the laser beam LB having an ultrashort pulse width. Therefore, when the ratio of the intensity of the laser beam LB having an ultrashort pulse width to the intensity of the laser beam LB having a nanosecond pulse width increases, an area (or width) of an HAZ may decrease.

Also, as described above, the laser beam LB having an ultrashort pulse width may process a relatively narrow region, and thus, it may be required to appropriately adjust the ratio of the intensity of the laser beam LB having an ultrashort pulse width to the intensity of the laser beam LB having a nanosecond pulse width. For example, the ratio (USP/NSP) of the intensity of the laser beam LB having an ultrashort pulse width to the intensity of the laser beam LB having a nanosecond pulse width may be controlled to about 10% or more. When the ratio (USP/NSP) of the intensity of the laser beam LB having an ultrashort pulse width to the intensity of the laser beam LB having a nanosecond pulse width is about 10% or more, a wide process area may be secured while minimizing the width of an HAZ. However, the numerical range may be at least one embodiment and may be variously changed based on the elements of the wafer processing apparatus 10.

The ratio (USP/NSP) of the intensity of the laser beam LB having an ultrashort pulse width to the intensity of the laser beam LB having a nanosecond pulse width may be adjusted by the beam shaper 300 and/or the beam compressor 400. For example, the beam shaper 300 may decrease the intensity of the center region of a laser beam LB and may increase the intensity of the outer region of the laser beam LB. The intensity of the center region of a laser beam LB may correspond to the intensity of the laser beam LB, and the intensity of the outer region of the laser beam LB may correspond to the intensity of a laser beam LB having an ultrashort pulse width.

Also, the beam compressor 400 may compress at least a portion of the laser beam LB to generate the laser beam LB having an ultrashort pulse width. As described above, in a case in which a ratio of each of a compression region and a mirror region is adjusted, the ratio (USP/NSP) of the intensity of the laser beam LB having an ultrashort pulse width to the intensity of the laser beam LB having a nanosecond pulse width may be adjusted.

That is, the wafer processing apparatus 10 according to at least one embodiment may adjust the ratio (USP/NSP) of the intensity of the laser beam LB having an ultrashort pulse width to the intensity of the laser beam LB having a nanosecond pulse width to reduce an area of an HAZ. Accordingly, the wafer processing apparatus 10 having high reliability and a high process speed may be provided.

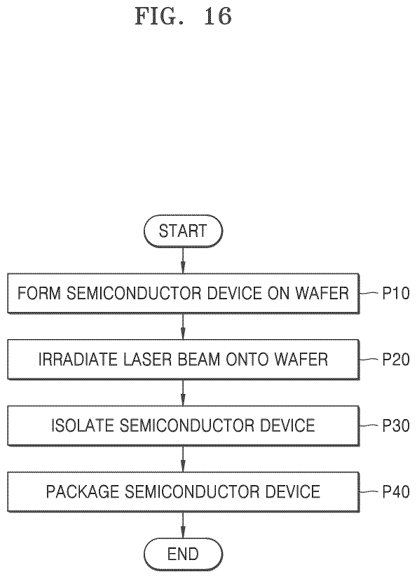

FIG. 16 is a flowchart illustrating a method of manufacturing a semiconductor device, according to at least one embodiment. FIG. 16 may be described in conjunction with FIGS. 1 to 15. The manufacturing a semiconductor device may be performed, for example, in a device manufacturing apparatus including at least one processing chamber including, e.g., a transfer chamber, and plurality of processing chambers. In at least one embodiment, the device manufacturing apparatus may include a transfer device (e.g., a robotic arm, a conveyer belt, etc.) configured to transfer wafers between the transfer chamber and/or the plurality of processing chambers. The plurality of processing chambers may be configured to perform operations in the manufacturing of the semiconductor device (e.g., deposition, oxidation, etching, separating etc.) and may be controlled by processing circuitry.

Referring to FIG. 16, first, a semiconductor device may be formed in a wafer W in operation P10. The wafer W may include a plurality of device formation regions where semiconductor devices are respectively formed and a scribe lane region which defines the plurality of device formation regions.

The wafer W may include, for example, a semiconductor element, such as Si and/or Ge and/or a compound semiconductor such as SiC, GaAs, InAs, and/or InP.

The wafer W may include a semiconductor device formed on the wafer W. The wafer W may include a plurality of device formation regions where the semiconductor device is formed and a scribe lane region SL which defines the plurality of device formation regions.

A semiconductor device SD formed in the wafer W may be one of a memory device and a non-memory device. In some embodiments, the memory device may be a non-volatile memory semiconductor device such as flash memory, PRAM, MRAM, FeRAM, or RRAM. The flash memory may be, for example, V-NAND flash memory. In some other embodiments, the memory device may be a volatile memory semiconductor device such as DRAM or SRAM. For example, the memory device may be a volatile memory device where data is lost when power thereto is cut off. In some embodiments, the non-memory device may be a logic chip such as a CPU, a GPU, or an AP. In some embodiments, the non-memory device may be a measurement device, a communication device, a DSP, and/or a SoC.

A process of forming a semiconductor device may include i) an oxidation process of forming an oxide layer, ii) a lithography process including spin coating, exposure, and development, iii) a thin film deposition process, iv) a dry or wet etching process, and v) a metal wiring process.

The oxidation process may be a process which performs a chemical reaction between oxygen or vapor and a silicon substrate surface at a high temperature of about 800° C. to about 1,200° C. to form a thin and uniform silicon oxide layer. The oxidation process may include dry oxidation and wet oxidation. The dry oxidation may form an oxide layer through a reaction with an oxygen gas, and the wet oxidation may react oxygen with vapor to form an oxide layer.

According to some embodiments, an SOI structure may be formed on a substrate by an oxidation process. The substrate may include a buried oxide layer. According to some embodiments, the substrate may have various device isolation structures such as an STI.

The lithography process may be a process which transfers a circuit pattern, previously formed in a lithography mask, onto the substrate through exposure. The lithography process may be performed in the order of a spin coating process, an exposure process, and a development process.

The thin film deposition process may be, for example, one of atomic layer deposition (ALD), chemical vapor deposition (CVD), plasma-enhanced CVD (PECVD), metal organic CVD (MOCVD), physical vapor deposition (PVD), reactive pulsed laser deposition, molecular beam epitaxy, and direct current (DC) magnetron sputtering.

The dry etching process may be, for example, reactive ion etching (RIE), deep RIE (DRIE), ion beam etching (IBE), and argon (Ar) milling. As another example, a dry etching process capable of being performed on a wafer W may be an atomic layer etching (ALE) process. Also, a wet etching process capable of being performed on the wafer W may be an etching process which uses, as an etchant gas, at least one of Cl₂, HCl, CHF₃, CH₂F₂, CH₃F, H₂, BCL₃, SiCl₄, Br₂, HBr, NF₃, CF₄, C₂F₆, C₄F₈, SF₆, O₂, SO₂, and COS.

The metal wiring process may be a process which forms a conductive wiring (a metal wiring) so as to implement a circuit pattern for an operation of a semiconductor device. Transfer paths of ground, power, and a signal for operating semiconductor devices may be formed by the metal wiring process. The metal wiring may include gold, platinum, silver, aluminum, and tungsten.

According to some embodiments, an ion implantation process and a planarization process such as a chemical mechanical polishing (CMP) process may be performed in a process of forming a semiconductor device.

Subsequently, a laser beam LB may be irradiated onto the wafer W in operation P20. The laser beam LB output from the wafer processing apparatus 10 may be irradiated onto the wafer W. According to some embodiments, a surface of the wafer W may be coated before the laser beam LB is irradiated onto the wafer W, so as to prevent damage to wafer W.

The wafer processing apparatus 10, as described above with reference to FIGS. 1 to 12, may include the chirped laser beam generator 100, the beam transmission optical source 200, the beam shaper 300, the beam compressor 400, and the wafer supporter 500. The chirped laser beam source 100 may generate and irradiate a laser beam LB where wavelength components are time-serially arranged. The beam transmission optical source 200 may transfer the laser beam LB, generated by the chirped laser beam generator 100, to the beam shaper 300. The beam shaper 300 may shape a waveform of the laser beam LB. In detail, the beam shaper 300 may decrease an intensity deviation between peaks of laser beams LB of the center region and the outer region of the laser beam LB. The laser beam LB shaped by the beam shaper 300 may be input to the beam compressor 400. The beam compressor 400 may locally compress the laser beam LB. For example, the beam compressor 400 may compress the outer region of the laser beam LB. The center region of the laser beam LB passing through the beam compressor 400 may have a pulse width of a nanosecond scale, and the outer region of the laser beam LB may have an ultrashort pulse width. The laser beam LB passing through the beam compressor 400 may be input to the wafer W.

The semiconductor device of the wafer W may be isolated by the laser beam LB irradiated onto the wafer W in operation P30. The laser beam LB irradiated onto the wafer W may be irradiated onto the surface of the wafer W. The process may be referred to as a laser ablation process. The laser ablation may form grooves in the wafer W to dice the wafer W.

The grooves formed in the wafer W may be diced by a mechanical process, and/or the wafer W may be diced by using a laser. For example, the mechanical process may include a process which dices the wafer W by using a blade wheel.

The laser ablation process may use a laser beam LB having a pulse width of a nanosecond scale and a laser beam LB having an ultrashort pulse width, so as to perform with high reliability and at a high process speed.

Subsequently, an isolated semiconductor device may be packaged in operation P40. A packaging process may include a wire bonding process, a molding process, a marking process, and a solder ball mount process.

Hereinabove, example embodiments have been described in the drawings and the specification. Embodiments have been described by using the terms described herein, but this has been merely used for describing the inventive concepts and has not been used for limiting a meaning or limiting the scope of the inventive concepts defined in the following claims. Therefore, it may be understood by those of ordinary skill in the art that various modifications and other equivalent embodiments may be implemented from the inventive concepts. Accordingly, the spirit and scope of the inventive concepts may be defined based on the spirit and scope of the following claims.

While the inventive concepts have been particularly shown and described with reference to embodiments thereof, it will be understood that various changes in form and details may be made therein without departing from the spirit and scope of the following claims.

1. A wafer processing apparatus comprising:
a laser apparatus configured to generate and irradiate a laser beam;
a beam shaper configured to generate a shaped laser beam by shaping a waveform of the laser beam; and
a beam compressor configured to locally compress the shaped laser beam,
wherein the wafer processing apparatus is configured such that the compressed laser beam is input to a wafer.

2. The wafer processing apparatus of claim 1, wherein the beam shaper is configured to
decrease intensity of a peak of a center region of the laser beam, and
increase intensity of a peak of a peripheral region of the laser beam.

3. The wafer processing apparatus of claim 1, wherein the beam shaper comprises at least one of a micro lens array and a diffraction optical element.

4. The wafer processing apparatus of claim 1, wherein, the wafer processing apparatus is configured such that, in the compressed laser beam input to the wafer, a pulse width of a center region differs from a pulse width of an outer region.

5. The wafer processing apparatus of claim 1, wherein, in the compressed laser beam input to the wafer, a pulse width of a center region is greater than a pulse width of an outer region.

6. The wafer processing apparatus of claim 1, wherein the beam compressor comprises a diffraction grating pattern.

7. The wafer processing apparatus of claim 1, wherein the laser beam generated and irradiated by the laser apparatus has a pulse width of a nanosecond scale.

8. A wafer processing apparatus comprising:
a chirped laser beam generator configured to generate and irradiate a laser beam such that wavelength components of the laser beam are time-serially arranged;
a beam shaper configured to generate a shaped laser beam by shaping a waveform of the laser beam irradiated by the chirped laser beam generator; and
a beam compressor configured to locally compress the shaped laser beam,
wherein the wafer processing apparatus is configured such that the compressed laser beam is input to a wafer.

9. The wafer processing apparatus of claim 8, wherein the beam compressor comprises
a mirror region configured to reflect the laser beam, and
a compression region configured to compress the laser beam.

10. The wafer processing apparatus of claim 9, wherein
the compression region is provided in a plurality of compression regions, and
the mirror region is disposed between two of the plurality of compression regions.

11. The wafer processing apparatus of claim 9, wherein a width of the compression region is about 0.5 millimeter (mm) to about 5 mm.

12. The wafer processing apparatus of claim 8, wherein the beam compressor is configured to compress an outer region of the laser beam.

13. The wafer processing apparatus of claim 8, wherein the wafer processing apparatus is configured to shape and compress the laser beam such that an intensity of a peak of an outer region of the laser beam is greater than intensity of a peak of a center region of the laser beam.

14. The wafer processing apparatus of claim 8, wherein the wafer processing apparatus is configured to input the laser beam to the wafer such that a direction toward an outer region, having an ultrashort pulse width, from a center region of the laser beam is perpendicular to an extension direction of a scribe lane region of the wafer.

15. The wafer processing apparatus of claim 8, wherein the wafer processing apparatus is configured to input the laser beam to the wafer such that
a center region of the laser beam input to the wafer has a pulse width of a nanosecond scale, and
an outer region of the laser beam input to the wafer has an ultrashort pulse width.

16. The wafer processing apparatus of claim 8, wherein the wafer processing apparatus is configured to input the laser beam to the wafer such that
a center region of the laser beam input to the wafer has a pulse width of about 20 picoseconds to about 300 femtoseconds, and
an outer region of the laser beam input to the wafer has a pulse width of about 1 femtosecond to about 200 femtoseconds.

17. A wafer processing apparatus comprising:
a chirped laser beam generator configured to generate and irradiate a first laser beam such that wavelength components of the first laser beam are time-serially arranged;
a beam shaper configured to generate a shaped laser beam by shaping a waveform of the first laser beam to generate a second laser beam;
a beam compressor configured to locally compress the second laser beam to generate a third laser beam; and
a wafer supporter configured to support a wafer,
wherein the wafer processing apparatus is configured such that the third laser beam is input to the wafer.

18. The wafer processing apparatus of claim 17, further comprising:
a beam transmission optical source configured to input the first laser beam to the beam shaper.

19. The wafer processing apparatus of claim 17, wherein the wafer processing apparatus is configured such that a ratio of intensity of an outer region of the first laser beam to intensity of a center region of the first laser beam is less than a ratio of intensity of an outer region of the second laser beam to intensity of a center region of the second laser beam.

20. The wafer processing apparatus of claim 17, wherein the beam compressor is configured to generate the third laser beam such that the third laser beam comprises a first region which is not compressed and a second region which is compressed, and
a width of the second region is about 0.5 mm to about 5 mm.

21.-25. (canceled)
